(19) United States
(12) Patent Application Publication
(10) Pub. No.: US 2010/0320478 A1
(43) Pub. Date: Dec. 23, 2010

(54) LIGHT-EMITTING DIODE DEVICE INCLUDING A CURRENT BLOCKING REGION AND METHOD OF MAKING THE SAME

(75) Inventors: Chih-Sheng Lin, Tainan County (TW); Che-Hsiung Wu, Tainan County (TW)

Correspondence Address: MARSH, FISCHMANN & BREYFOGLE LLP, 8055 East Tufts Avenue, Suite 450, Denver, CO, 80237, US

(73) Assignee: UBILUX OPTOELECTRONICS CORPORATION, Tainan County (TW)

(21) Appl. No.: 12/710,454

(22) Filed: Feb. 23, 2010

(30) Foreign Application Priority Data
Jun. 19, 2009 (TW) 098120613

(51) Int. Cl. H01L 33/00; H01L 21/30

(52) U.S. Cl. 257/79; 438/22; 257/E33.06; 257/E21.211

(57) ABSTRACT

A light-emitting diode device includes: a substrate; a light-emitting layered structure disposed on the substrate and including a first cladding layer, an active layer, and a second cladding layer; a first electrode; a second electrode disposed on the light-emitting layered structure; and a current blocking region provided in the light-emitting layered structure below the second electrode, and having a main portion that is aligned below and is as large as the second electrode, and an extension portion extending from the main portion and protruding beyond the second electrode to a distance ranging from 3 μm to 20 μm.

### CROSS-REFERENCE TO RELATED APPLICATION

This application claims priority of Taiwanese application No. 098120613, filed on Jun. 19, 2009.

### BACKGROUND OF THE INVENTION

1. Field of the Invention

This invention relates to a light-emitting diode device, more particularly to a light-emitting diode device including a current blocking region.

2. Description of the Related Art

Referring to FIG. 1, a conventional light-emitting diode device includes a substrate layer 11, a buffer layer 12 formed on the substrate layer 11, a light-emitting layered structure 13, a current blocking region 14, a conductive transparent layer 15, an n-contact electrode 16 and a p-contact electrode 17. The light-emitting layered structure 13 includes an n-contact layer 131, an n-type cladding layer 132, an active layer 133, a p-type cladding layer 134, and a p-contact layer 135. The n-contact electrode 16 is formed on an exposed region of the n-contact layer 131, and the p-contact electrode 17 is formed on the conductive transparent layer 15. The light-emitting layered structure 13 is capable of generating light when a working voltage is applied thereto through the electrodes 16, 17.

The p-contact layer 135 is subjected to a surface treatment, such as ion implantation or ion bombardment, thereby altering electrical conductivity of portions of the p-contact layer 135 so as to form the current blocking region 14. In addition, the current blocking region 14 is aligned with and disposed below the p-contact electrode 17.

Due to poor electrical conductivity, the current blocking region 14 can spread the applied current laterally to the region around the p-contact layer 135, thereby preventing the current from concentrating around the region beneath the p-contact electrode 17 such that overheating caused by current concentration can be alleviated and light-emitting uniformity and efficiency can be improved.

However, a current blocking region with arbitrary design does not provide a good improvement in spreading current. In practice, the width and thickness of the current blocking region 14 are material to the current spreading.

### SUMMARY OF THE INVENTION

Therefore, an object of the present invention is to provide a light-emitting diode device that can improve current spreading and light-emitting uniformity and efficiency.

Another object of this invention is to provide a method of making the light-emitting diode device.

According to one aspect of the present invention, a light-emitting diode device comprises a substrate; a light-emitting layered structure disposed on the substrate and including a first cladding layer, an active layer, and a second cladding layer; a first electrode electrically coupled to the first cladding layer; a second electrode disposed on the light-emitting layered structure and electrically coupled to the second cladding layer; and a current blocking region provided in the light-emitting layered structure below the second electrode, and having a main portion that is aligned below and is as large as the second electrode and an extension portion extending from the main portion and protruding beyond the second electrode to a distance ranging from 3 μm to 20 μm.

According to another aspect of the present invention, a method of making a light-emitting diode device comprises: (a) providing a substrate; (b) forming on the substrate a semiconductor layered structure including a first cladding layer, an active layer, and a second cladding layer; (c) forming a current blocking region in the semiconductor layered structure, the current blocking region having a main portion and an extension portion extending from the main portion; (d) forming a first electrode electrically coupled to the first cladding layer; and (e) forming a second electrode on the semiconductor layered structure above the current blocking region. The second electrode is electrically coupled to the second cladding layer, aligned above the main portion of the current blocking region and provided with a size as large as that of the main portion. The extension portion protrudes beyond the second electrode to a distance ranging from 3 μm to 20 μm.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is a schematic view of a conventional light-emitting device;

FIG. 2 is a schematic view of the first preferred embodiment of a light-emitting diode device according to this invention;

FIG. 3 is a plan view of the first preferred embodiment;

FIG. 4 is a flowchart to illustrate consecutive steps of the method of making the light-emitting diode device according to this invention;

FIGS. 5a to 5e are views to illustrate the consecutive steps of a method of making a current blocking region;

FIGS. 6a to 6g are views to illustrate the consecutive steps of another method of making the current blocking region;

FIG. 7 is a plot of width versus light output power of the first preferred embodiment;

FIG. 8 is a plot of thickness versus light output power of the first preferred embodiment;

FIG. 9 is a schematic view of the second preferred embodiment of a light-emitting diode device according to this invention; and

FIG. 10 is a plan view of the second preferred embodiment.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

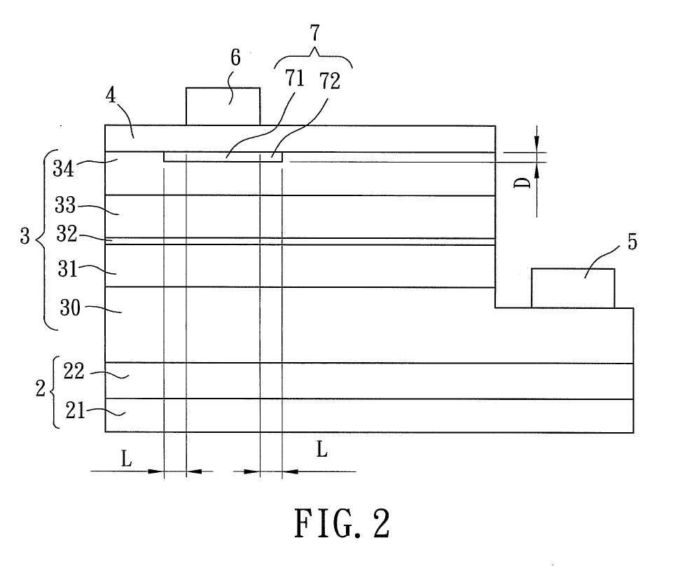

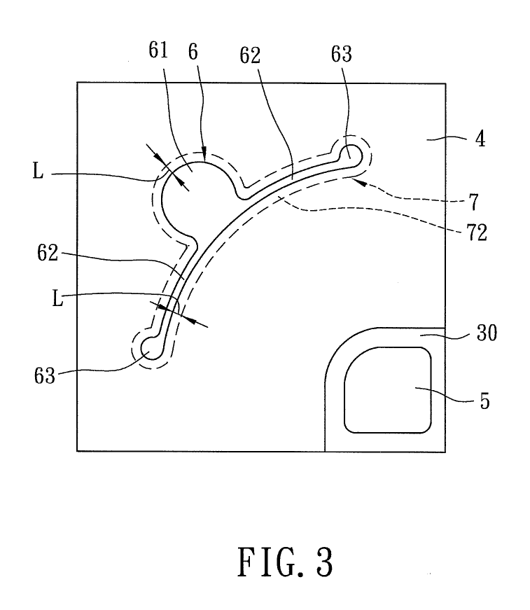

Referring to FIGS. 2 and 3, a light-emitting diode device of the first preferred embodiment according to this invention includes a substrate 2, a light-emitting layered structure 3, a conductive transparent layer 4, first and second electrodes 5, 6 electrically coupled to the light-emitting layered structure 3, and a current blocking region 7.

The substrate 2 includes a base layer 21 and a buffer layer 22 formed on the base layer 21. In this embodiment, the base layer 21 is made from sapphire, and the buffer layer 22 is made of un-doped gallium nitride (GaN).

The light-emitting layered structure 3 is formed on the buffer layer 22 of the substrate 2 and includes a first contact layer 30, a first cladding layer 31, an active layer 32, a second cladding layer 33, and a second contact layer 34 in sequence.

In this embodiment, the first contact layer 30 is made of an n-type semiconductor material, formed on a surface of the buffer layer 22 and in ohmic contact with the first electrode 5. The first cladding layer is made of an n-type gallium nitride-based semiconductor material. The active layer 32 is made of gallium nitride-based material including homostructure, heterostructure or multiple quantum well structure. The second cladding layer 33 is made of a p-type gallium nitride-based semiconductor material. The second contact layer 34 is made of a p-type semiconductor material and formed on the second cladding layer 33.

The conductive transparent layer 4 is made of indium tin oxide (ITO) and has a high transparency and a good electrical conductivity. The first and second electrodes 5, 6 are adapted for accepting a working voltage applied thereto and providing the working voltage for the light-emitting layered structure 3 to generate light. The first electrode 5 is formed on an exposed region of the first cladding layer 31, thereby being electrically coupled thereto. The second electrode 6 is formed on a surface of the conductive transparent layer 4, and is electrically coupled to the second cladding layer 33 through the conductive transparent layer 4 and the second contact layer 34. Moreover, the second electrode 6 has a central part 61, two connecting strips 62 extending from the central part 61, and two end nodes 63 respectively connected to the connecting strips 62. The central part 61 is larger than the connecting strips 62 and the end nodes 63. In practice, the shape of the second electrode 6 in this invention is not limited to that shown in FIG. 3.

The current blocking region 7 is provided in a local surface of the second contact layer 34, is disposed between the second contact layer 34 and the conductive transparent layer 4, and corresponds in position to the second electrode 6. The current blocking region 7 has a shape corresponding to and a size larger than that of the second electrode 6. Therefore, the current blocking region 7 has a main portion 71 that is aligned below and that is as large as the second electrode 6, and an extension portion 72 uniformly extending around the whole of the main portion 71. The extension portion 72 has a width (L) that is defined by a distance that the extension portion 72 protrudes beyond the second electrode 6. The width (L) measured at any position of the extension portion 72 is the same and preferably ranges from 3 μm to 20 μm. Preferably, the current blocking region 7 has a thickness (D) not less than 4 Å, more preferably, not less than 10 Å, and most preferably, not less than 13 Å.

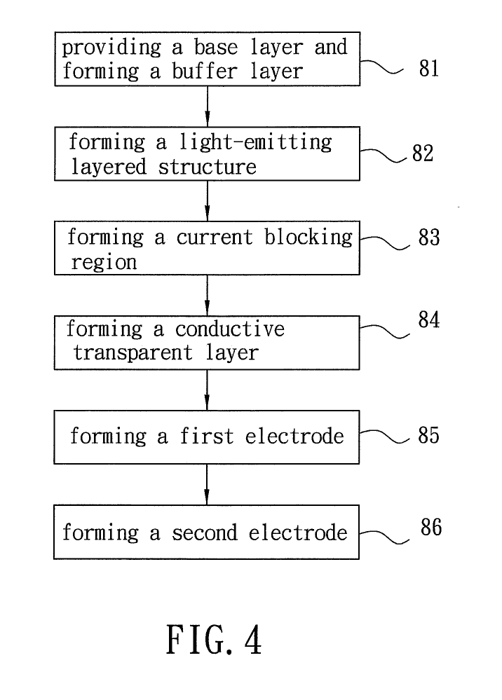

Referring to FIGS. 2 and 4, a method of making the light-emitting diode device according to this invention includes steps 81 to 86.

In step 81, the GaN buffer layer 22 is grown on the sapphire base layer 21 using metal organic chemical vapor disposition (MOCVD).

In step 82, the light-emitting layered structure 3 is formed on the buffer layer 22. The light-emitting layered structure 3 includes the first cladding layer 31, the active layer 32, the second cladding layer 33, and the second contact layer 34.

In step 83, the second contact layer 34 is subjected to a surface treatment, thereby forming the current blocking region 7 having the main portion 71 and the extension portion 72. The surface treatment is conducted through ion implantation, ion bombardment or thermal diffusion. The shape and size of the current blocking region 7 are determined through photolithography techniques. By forming the current blocking region 7 which has poor electrical conductivity, a current blocking right below the second electrode 6 is obtained such that the current can spread laterally.

The material used in ion implantation or ion bombardment is selected from the group consisting of carbon (C), boron (B), phosphorous (P), sulfur (S), silicon (Si), arsenic (As), gallium (Ga), indium (In), sodium (Na), hydrogen (H), fluorine (F), chlorine (Cl), oxygen (O), nitrogen (N), and combinations thereof.

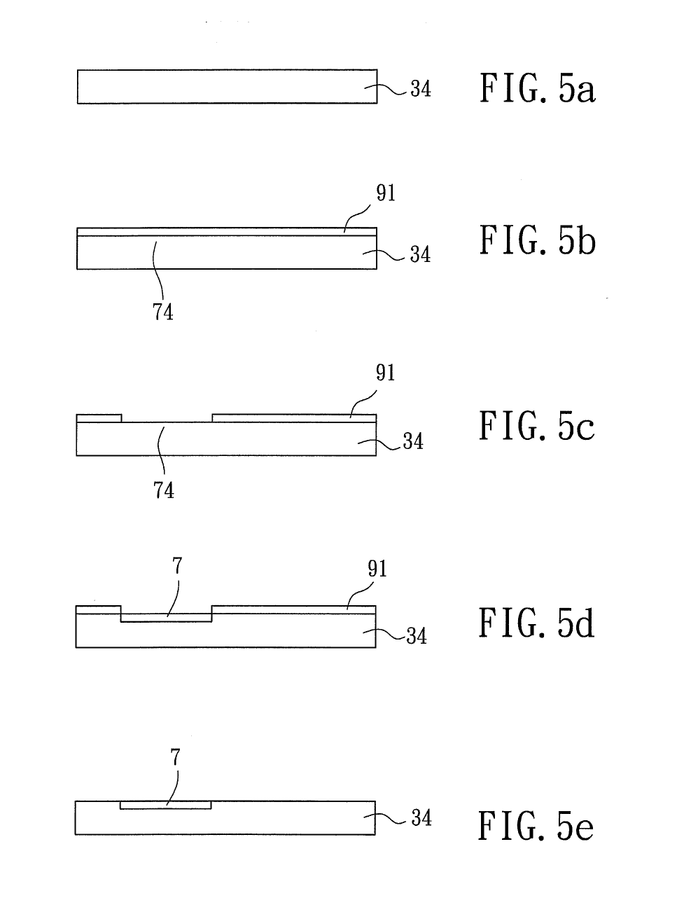

FIGS. 5a to 5e illustrate the consecutive steps of a method of making the current blocking region 7. A photoresist layer 91 is coated on the second contact layer 34 and is patterned using photolithography techniques so as to expose a portion 74 of the second contact layer 34. The portion 74 of the second contact layer 34 exposed from the photoresist layer 91 is subjected to a surface treatment, such as ion implantation or ion bombardment, so as to form the current blocking region 7. Subsequently, the remainder of the photoresist layer 91 is removed.

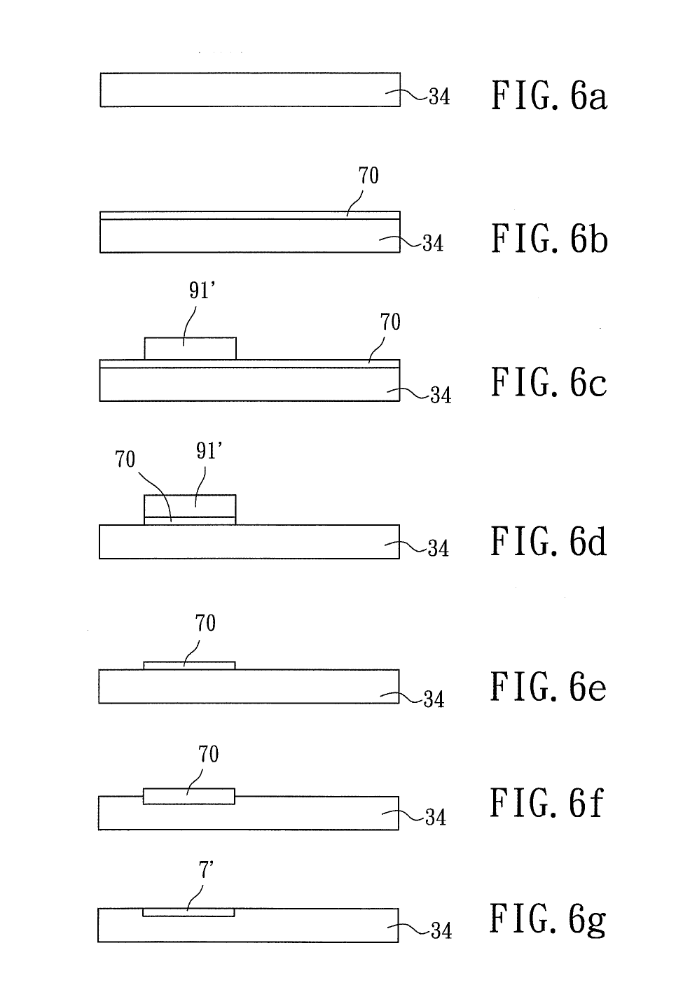

FIGS. 6a to 6g illustrate the consecutive steps of another method of making the current blocking region 7. First, a current blocking material 70 containing silicon, such as silicon dioxide (SiO₂), is formed on the second contact layer 34. A photoresist layer 91′ is coated on the current blocking material 70 at a predetermined position. The current blocking material 70 exposed from the photoresist layer 91′ is removed using photolithography techniques and then the photoresist layer 91′ is removed. Subsequently, the current blocking material 70 is subjected to a thermal treatment so that the current blocking material 70 diffuses into the second contact layer 34 so as to form the current blocking region 7′.

Referring back to FIGS. 2 and 4, in step 84, the conductive transparent layer 4 is formed on the second contact layer 34.

In step 85, the first electrode 5 is formed on an exposed region of the first contact layer 30.

In step 86, the second electrode 6 is formed on the conductive transparent layer 4. The second electrode 6 has a shape corresponding to and a size smaller than that of the current blocking region 7. The second electrode 6 is disposed over the current blocking region 7 and aligned above the main portion 71 of the current blocking region 7.

It is noted that the above-mentioned steps should not be limited to the above sequence. For example, step 86 can be conducted prior to step 85.

By virtue of the current blocking region 7 which is disposed below and larger than the second electrode 6, the applied current is prevented from concentrating around the region beneath the second electrode 6, and is allowed to spread uniformly and laterally, thereby enhancing light-emitting uniformity and efficiency.

### First Experiments

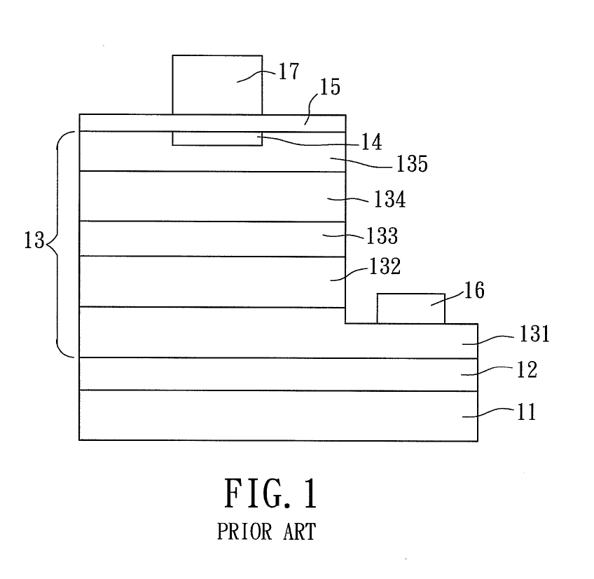

In the first experiments, Samples 1-8 (S1-8) corresponding to the embodiment shown in FIG. 1 and Comparative Sample 1 (CS1) are prepared. The experiments are performed using the working voltage of 20 mA to evaluate the light output power of the samples. The thickness of the current blocking regions 7 of Samples 1-8 and Comparative Sample 1 is 36 Å. However, the current blocking region of Comparative Sample 1 differs from that of Samples 1-8 in the width (L) of the extension portion 72. The width of the extension portion 72 of Comparative Example is zero (L=0), which indicates that the current blocking region 7 is the same size as the second electrode 6.

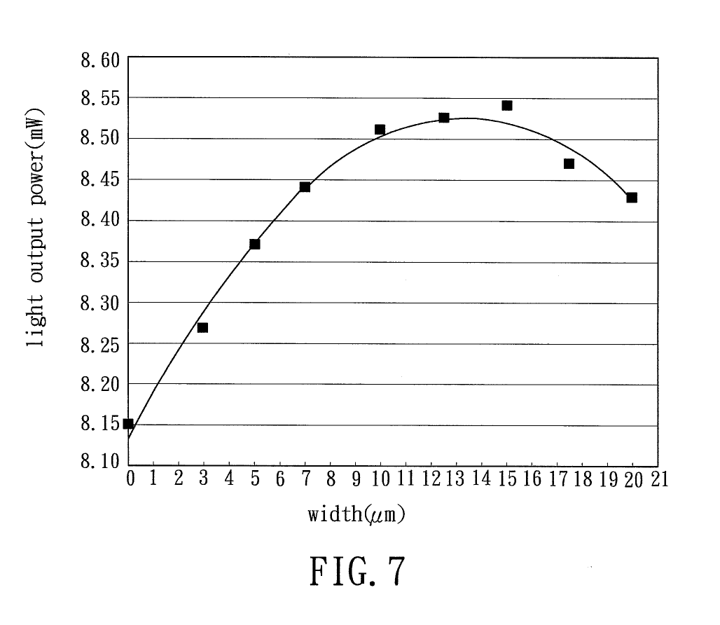

Referring to Table 1 and FIG. 7, the results show that Comparative Sample 1 has a light output power of 8.15 mW. In Samples 1-8, when the width (L) is 3 μm, the light output power is 8.27 mW. Furthermore, when the width (L) is increased to a value of 15μm (S6), the light output power is increased to a maximum value of 8.54 mW, which is an increase of 4.8% compared to that of Comparative Sample 1. However, when the width (L) is further increased, for example, the width is 20 μm (S8), the light output power is slightly decreased but still has 3.44% increase as compared to that of Comparative Sample 1. However, due to an overly large width, the current will flow into a peripheral region, which has a reduced area for current flow, thereby causing the current to crowd in the reduced area. Therefore, according to this invention, the width (L) ranges from 3 μm to 20 μm.

TABLE 1

| | CS1 | S1 | S2 | S3 | S4 | S5 | S6 | S7 | S8 |
|---|---|---|---|---|---|---|---|---|---|
| L(μm) | 0 | 3 | 5 | 7 | 10 | 12.5 | 15 | 17.5 | 20 |
| Light | 8.15 | 8.27 | 8.37 | 8.44 | 8.51 | 8.53 | 8.54 | 8.47 | 8.43 |
| output | | | | | | | | | |
| power | | | | | | | | | |
| (mW) | | | | | | | | | |

### Second Experiments

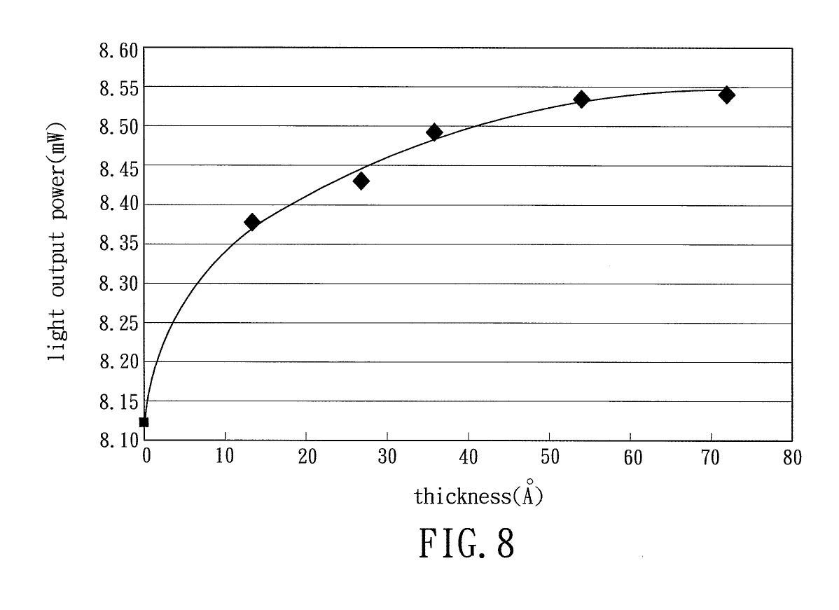

Referring to FIG. 8 and Table 2, the width (L) of the current blocking region 7 of Samples 9-13 (S9-13) is 10 μm. Comparative Sample 2 (CS2) does not have the current blocking region 7. The thickness of the current blocking region 7 is varied in Samples 9-13. The second experiments are performed using the working voltage of 20 mA.

The results show that Comparative Sample 2 has a light output power of 8.12 mW and that the light output power is larger than 8.12 mW in Samples 9-13 which have the current blocking region 7. Generally, the light output power is increased with increasing thickness. When the thickness is increased to 72 Å, the light output power is up to a maximum value of 8.54 mW.

It is worth mentioning that when the thickness is too small, the current blocking effect of the current blocking region 7 is insufficient so that the current will be unable to spread uniformly in lateral directions. When the thickness is increased, the effect on the current blocking is raised. However, when the thickness is larger than a value, the current blocking effect becomes saturated. As shown in Table 2, when the thickness is 72 Å (see sample 13), the light-emitting efficiency is not increased significantly.

Therefore, according to the present invention, the thickness of the current blocking region 7 is not smaller than 4 Å, preferably not smaller than 10 Å, more preferably not smaller than 13 Å. In FIG. 8, when the thickness increases from 0 Å to 4 Å, the light output power increases about 2%. FIG. 8 further shows that the light output power increases substantially when the thickness increases to 10 Å, and that the light output power increases further when the thickness is 13 Å.

TABLE 2

| | CS2 | S9 | S10 | S11 | S12 | S13 |
|---|---|---|---|---|---|---|
| D(Å) | 0 | 13.5 | 27 | 36 | 54 | 72 |
| Light | 8.12 | 8.38 | 8.43 | 8.49 | 8.53 | 8.54 |
| output | | | | | | |
| power | | | | | | |
| (mW) | | | | | | |

It is worth mentioning that the second electrode of the conventional light-emitting diode device usually has the same area as that of a current blocking region. During processing, if the second electrode is not aligned with the current blocking region, portions of the second electrode will protrude beyond the current blocking region, thereby adversely affecting the current spreading. The current blocking region 7 of the present invention has an area larger than that of the second electrode 6, which has an advantage in that the second electrode 6 can be entirely included in the current blocking region 7 even when the second electrode 6 slightly deviates from the current blocking region 7.

In addition, since the current blocking region is provided in the second contact layer 34, the present invention permits the surface treatment to be performed after the epitaxial layers are completed. However, the current blocking region 7 can also be formed in the second cladding layer 33 and below the second contact layer 34.

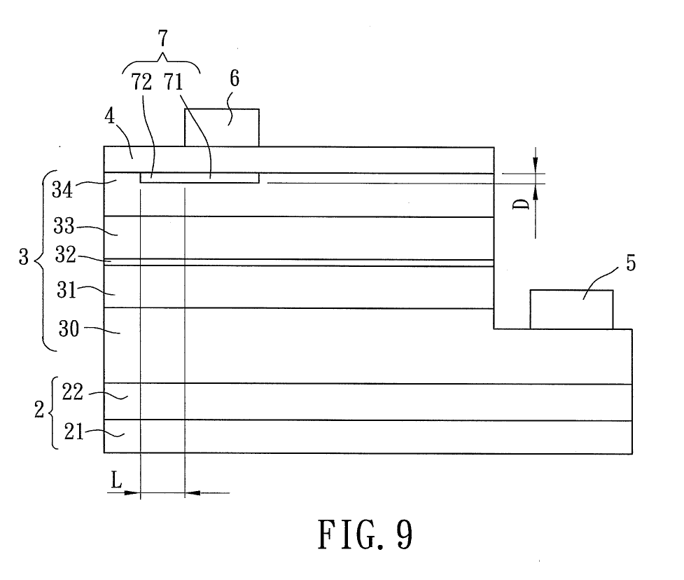

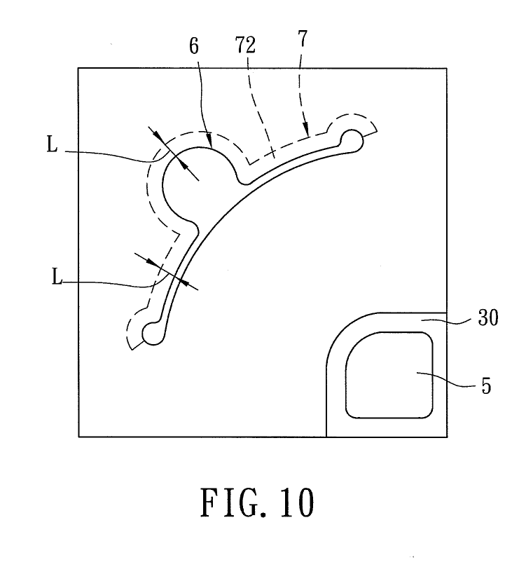

Referring to FIGS. 9 and 10, the second preferred embodiment of the present invention differs from the first preferred embodiment in that the extension portion 72 extends from parts of the main portion 71 and merely protrudes beyond one side of the second electrode 6 by the distance (L).

By virtue of the extension portion 72 of the current blocking region 7 protruding beyond at least one side of the second electrode 6, a current blocking area can be enlarged. In addition, the shape of the current blocking region 7 can vary depending on the shape of the second electrode 6.

With the invention thus explained, it is apparent that various modifications and variations can be made without departing from the spirit of the present invention. It is therefore intended that the invention be limited only as recited in the appended claims.

What is claimed is:

1. A light-emitting diode device comprising:
a substrate;
a light-emitting layered structure disposed on said substrate and including a first cladding layer, an active layer, and a second cladding layer;
a first electrode electrically coupled to said first cladding layer;
a second electrode disposed on said light-emitting layered structure and electrically coupled to said second cladding layer; and
a current blocking region provided in said light-emitting layered structure below said second electrode, and having a main portion that is aligned below and is as large as said second electrode, and an extension portion extending from said main portion and protruding beyond said second electrode to a distance ranging from 3 μm to 20 μm.

2. The light-emitting diode device of claim 1, wherein said current blocking region has a thickness not less than 4 Å.

3. The light-emitting diode device of claim 2, wherein said current blocking region has a thickness not less than 10 Å.

4. The light-emitting diode device of claim 3, wherein said current blocking region has a thickness not less than 13 Å.

5. The light-emitting diode device of claim 1, wherein said light-emitting layered structure further includes a first contact layer sandwiched between said substrate and said first cladding layer, and a second contact layer formed on said second cladding layer, said first electrode being formed on said first contact layer, said current blocking region being provided in said second contact layer.

6. The light-emitting diode device of claim 5, wherein said light-emitting layered structure further includes a conductive transparent layer formed on said second contact layer and below said second electrode, said current blocking region being interposed between said conductive transparent layer and said second contact layer.

7. The light-emitting diode device of claim 1, wherein said extension portion extends from parts of said main portion.

8. The light-emitting device of claim 1, wherein said extension portion extends around the whole of said main portion.

9. A method of making a light-emitting diode device comprising:
(a) providing a substrate;
(b) forming on the substrate a semiconductor layered structure including a first cladding layer, an active layer, and a second cladding layer;
(c) forming a current blocking region in the semiconductor layered structure, the current blocking region having a main portion and an extension portion extending from the main portion;
(d) forming a first electrode electrically coupled to the first cladding layer; and
(e) forming a second electrode on the semiconductor layered structure above the current blocking region, the second electrode being electrically coupled to the second cladding layer, aligned above the main portion of the current blocking region and provided with a size as large as that of the main portion;
wherein the extension portion protrudes beyond the second electrode to a distance ranging from 3 μm to 20 μm.

10. The method of making a light-emitting diode device of claim 9, wherein the semiconductor layered structure is subjected to a surface treatment to form the current blocking region.

11. The method of making a light-emitting diode device of claim 10, wherein the surface treatment is conducted through ion implantation, ion bombardment or thermal diffusion.

12. The method of making a light-emitting diode device of claim 9, wherein the semiconductor layered structure further includes a first contact layer sandwiched between the substrate and the first cladding layer, and a second contact layer formed on the second cladding layer.

13. The method of making a light-emitting diode device of claim 12, wherein the second contact layer is subjected to a surface treatment to form the current blocking region.

14. The method of making a light-emitting diode device of claim 13, wherein the surface treatment is conducted through ion implantation, ion bombardment or thermal diffusion.

15. The method of making a light-emitting diode device of claim 9, further comprising forming a conductive transparent layer on the semiconductor layered structure.

16. The method of making a light-emitting diode device of claim 9, wherein the current blocking region has a thickness not less than 4 Å.

17. The method of making a light-emitting diode device of claim 16, wherein the current blocking region has a thickness not less than 10 Å.

18. The method of making a light-emitting diode device of claim 17, wherein the current blocking region has a thickness not less than 13 Å.
